(19) United States
(12) Patent Application Publication
(10) Pub. No.: US 2008/0175144 A1
(43) Pub. Date: Jul. 24, 2008

(54) Method, apparatus and system for establishing return label switch path in multi-protocol label switching system

(75) Inventors: Chaogang Lu, Shenzhen (CN); Wei Fu, Shenzhen (CN); Xingyue Quan, Shenzhen (CN); Xiaodong Li, Shenzhen (CN); Jianfei He, Shenzhen (CN)

Correspondence Address: SUGHRUE MION, PLLC, 2100 PENNSYLVANIA AVENUE, N.W., SUITE 800, WASHINGTON, DC, 20037, US

(73) Assignee: HUAWEI TECHNOLOGIES CO., LTD., Shenzen (CN)

(21) Appl. No.: 11/878,056

(22) Filed: Jul. 20, 2007

Related U.S. Application Data
(63) Continuation of application No. PCT/CN2006/000185, filed on Jan. 27, 2006.

(30) Foreign Application Priority Data
Jan. 27, 2005 (CN) 200510002995.6

(51) Int. Cl. G01R 31/08; H04L 12/28; H04L 12/56

(52) U.S. Cl. 370/228; 370/395.5

(57) ABSTRACT

A method, an apparatus and a system for establishing a return LSP in an MPLS system are disclosed. The method includes: recording a path of a protection LSP; constructing an explicit routing object along the reverse of the path of the protection LSP; establishing the return LSP according to the explicit routing object. It is possible to effectively avoid that a return LSP overlaps with a working LSP in accordance with the embodiments of the present invention, thereby ensuring the transmission of LSP failure information via the return LSP in the case that the working LSP fails or transmission quality is impaired, and ensuring the normal operation of protection switching.

### FIELD OF THE INVENTION

The present invention relates to the Label Switch Path (LSP) protection method in Multi-Protocol Label Switching (MPLS) technologies, and more particularly, to a method, an apparatus and a system for establishing a return LSP in an MPLS system.

### BACKGROUND OF THE INVENTION

MPLS is an emerging routing and switching technology for providing high-speed reliable transmission of data packets. An IP router, an ATM switch and a Frame Relay (FR) switch using the MPLS are called by a joint name, Label Switch Router (LSR). A transmission channel composed of a set of interconnected LSRs is referred to as an LSP. To enable a packet to be transmitted to a sink node correctly, an LSP is generally protected by using a 1+1 protection mode or a 1:1 protection mode in an MPLS network.

In the 1+1 protection mode, a dedicated backup LSP is used as a protection LSP of a working LSP in the MPLS network. The working LSP and the protection LSP connect to each other at a source node and a sink node of traffic. The source node duplicates the working traffic on the protection LSP, and sends the working traffic to the sink node simultaneously. In a normal condition, the sink node only receives a packet transmitted by the working LSP. When the working LSP fails or the transmission quality thereof is unable to meet a requirement, the sink node will receive the packet transmitted by the protection LSP, i.e. when the working LSP fails, the sink node will switch the working traffic to the protection LSP.

In the 1:1 protection mode, a working LSP and a protection LSP also connect to each other at a source node and a sink node of traffic. The difference from the 1+1 protection mode is that, in a normal condition, the protection LSP is able to transmit extra traffic; when the working LSP fails and the working traffic needs to be transmitted by the protection LSP, the source node and the sink node will switch the working traffic to the protection LSP for transmission.

In the above two protection modes, the failure of the working LSP is usually detected by the sink node according to an MPLS protocol. Therefore, to switch the working traffic to the protection LSP, it is necessary to send LSP failure information to the source node when the sink node detects a failure; as a result, after receiving the LSP failure information, the source node will switch the working traffic to the protection LSP for transmission to complete the protection switching. As can be seen, to implement the above protection switching procedure, an LSP, from the sink node to the source node, for transmitting the LSP failure information is further needed between the source node and the sink node apart from the working LSP and the protection LSP, which is referred to as a return LSP herein. In this way, in the case of detecting the failure of the working LSP, the sink node will send the LSP failure information to the source node via the return LSP, so as to implement the protection switching of the working traffic.

FIG. 1 is a schematic diagram illustrating a working LSP, a protection LSP and a return LSP in an MPLS network. Referring to FIG. 1, to protect traffic to be transmitted, it is necessary to establish three LSPs between Source node A and Sink node B, i.e. a working LSP, for transmitting the traffic in a normal condition, passing through LSRs of A-a1-a2-B successively, a protection LSP, for transmitting the traffic in the case that the working LSP fails or transmission quality is impaired, passing through LSRs of A-b1-b2-b3-B successively, and a return LSP, for transmitting the LSP failure information in the case that the sink node detects that the working LSP fails, passing through LSRs of B-c2-c1-A successively.

According to an MPLS protocol, a working LSP and a protection LSP may be established by means of a routing algorithm or a manually-designated mode; however, a method for effectively determining a return LSP is not given in the MPLS protocol. In general, the return LSP may also be established by means of a routing algorithm.

In the case of determining a return LSP by means of a routing algorithm, it is possible that the determined return LSP overlaps with the working LSP, i.e. the return LSP is established along the reverse of the path of the working LSP, i.e., the reverse path of the working LSP. As a result, once the overlapping networks fail, LSP failure information sent by the sink node is unable to be transmitted to the source node correctly via the return LSP, which eventually results in the failure of the protection switching.

### SUMMARY OF THE INVENTION

Embodiments of the present invention provide a method, an apparatus and a system for establishing a return Label Switch Path (LSP) in a Multi-Protocol Label Switching (MPLS) system to effectively avoid that the return LSP overlaps with a working LSP, which makes it possible to guarantee that LSP failure information sent by a sink node can be received by a source node correctly in the case that the working LSP fails, thereby ensuring the normal operation of protection switching.

A method for establishing a return Label Switch Path (LSP) in a Multi-Protocol Label Switching (MPLS) system includes:

recording, by a last node in a procedure of establishing a protection LSP, a path of the protection LSP upon establishing the protection LSP;

constructing, by the last node, a first explicit routing object along the reverse of the path of the protection LSP; and

establishing, by each node on the protection LSP, a return LSP according to the first explicit routing object.

The recording the path of the protection LSP path includes:

obtaining the path of the protection LSP recorded in an explicit routing object or a record routing object carried in a protection LSP establishment request, and storing the path of the protection LSP.

A node initiating to establish the protection LSP is a source node of traffic;

the last node is a sink node of the traffic.

A node initiating to establish the protection LSP is a sink node of traffic;

the last node is a source node the traffic.

The constructing the first explicit routing object along the reverse of the path of the protection LSP includes:

recording, according to the reverse of a sequence of all the nodes on the protection LSP, all the nodes on the protection LSP in the first explicit routing object successively.

The method further includes:

establishing a protection LSP of the return LSP.

The establishing the protection LSP of the return LSP includes:

recording, by a last node in the procedure of establishing a working LSP, a path of the working LSP upon establishing the working LSP;

constructing, by the last node in the procedure of establishing a working LSP, a second explicit routing object along the reverse of the path of the working LSP;

establishing the protection LSP of the return LSP according to the second explicit routing object.

The recording the path of the working LSP includes:

obtaining the path of the working LSP recorded by an explicit routing object or a record routing object carried in a working LSP establishment request, and storing the path of the working LSP.

The constructing the second explicit routing object along the reverse of the path of the working LSP includes:

recording, according to the reverse of a sequence of all the nodes on the working LSP, all the nodes on the working LSP in the second explicit routing object successively.

A system for establishing a return Label Switch Path (LSP) in a Multi-Protocol Label Switching (MPLS) system includes:

a first node, for recording a path of a protection LSP upon establishing the protection LSP, and constructing a first explicit routing object along the reverse of the path of the protection LSP; and

at least one second node, for establishing a return LSP according to the first explicit routing object.

The first node is further used for recording a path of a working LSP upon establishing the working LSP, and constructing a second explicit routing object along the reverse of the path of the working LSP;

the at least one second node is further used for establishing the protection LSP of the return LSP according to the second explicit routing object.

An apparatus for establishing a return Label Switch Path (LSP) in a Multi-Protocol Label Switching (MPLS) system includes:

a first unit, for recording a path of a protection LSP upon establishing the protection LSP;

a second unit, for constructing a first explicit routing object along the reverse of the path of the protection LSP;

a third unit, for establishing the return LSP according to the first explicit routing object.

The first unit is further used for recording a path of a working LSP upon establishing the working LSP;

the second unit is further used for constructing a second explicit routing object along the reverse of the path of the working LSP;

the third unit is further used for establishing the protection LSP of the return LSP according to the second explicit routing object.

As can be seen, the method for establishing a return LSP in an MPLS system in accordance with the embodiments of the present invention obtains a path of the protection LSP by carrying an explicit routing object or a record routing object in a protection LSP establishment request, and establishes a return LSP along the reverse of the path of the protection LSP, so as to effectively avoid that the return LSP overlaps with the working LSP. In accordance with the embodiments of the present invention, it is possible to guarantee the transmission of LSP failure information via the return LSP in the case that the working LSP fails or transmission quality is impaired, thereby ensuring the normal operation of protection switching.

In accordance with the embodiments of the present invention, similar to the above method, another protection LSP is established by regarding the reverse path of a working LSP as a return LSP, which makes it possible to guarantee the transmission of LSP failure information via a protection LSP of the return LSP in the reverse of the working LSP in the case that the return LSP fails, thereby further guaranteeing the reliability of the transmission of LSP failure information.

### BRIEF DESCRIPTION OF THE DRAWINGS

FIG. 1 is a schematic diagram illustrating a working LSP, a protection LSP and a return LSP established between a source node and a sink node in the prior art.

FIG. 2 is a schematic diagram illustrating a working LSP, a protection LSP and a return LSP established between a source node and a sink node in accordance with an embodiment of the present invention.

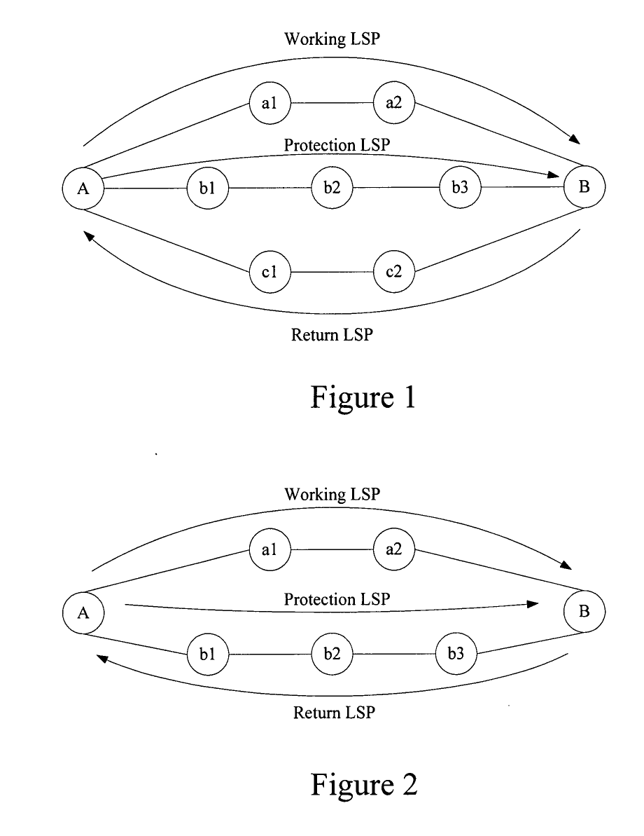

### EMBODIMENTS OF THE INVENTION

The present invention is hereinafter further described in detail with reference to accompanying drawings as well as embodiments so as to make the technical solution and merits thereof more apparent.

To avoid that a working LSP overlaps with a return LSP established according to a routing algorithm, embodiments of the present invention provide a method for establishing a return LSP. The method including: establishing a return LSP along the reverse of a path of a protection LSP to enable the return LSP to overlap with the protection LSP, which makes it possible to guarantee that LSP failure information sent by a sink node can be received correctly by a source node and switch working traffic to the protection LSP in the case that the working LSP fails.

FIG. 2 is a schematic diagram illustrating a working LSP, a protection LSP and a return LSP established between a source node and a sink node in accordance with an embodiment of the present invention, wherein A-a1-a2-B are LSRs through which the working LSP passes; A-b1-b2-b3-B are LSRs through which the protection LSP passes; and B-b3-b2-b1-A are LSRs through which the return LSP passes. With reference to FIG. 2, the return LSP is established along the reverse of a path of the protection LSP.

The method of the present invention will be hereinafter described in detail with respect to embodiments. The establishment of a protection LSP may be initiated by a source node or a sink node. In the case that the establishment of the protection LSP is initiated by the source node, a sink node is the last node of the procedure of establishing the protection LSP, and therefore, the establishment of the return LSP is initiated by the sink node.

### Embodiment 1

The method for establishing a return LSP described in the present embodiment includes the following steps.

Step 101: a source node sends a protection LSP establishment request carrying an explicit routing object to initiate the establishment of a protection LSP; each LSR on the protection LSP establishes the protection LSP according to a path recorded in an explicit routing object.

A source node in an MPLS network is able to establish an LSP in an explicit routing mode. In the explicit routing mode, the source node predetermines a path of the protection LSP, records the path in the explicit routing object carried in the protection LSP establishment request, and sends the protection LSP establishment request to a next hop LSR recorded in the explicit routing object. In the establishment of the protection LSP, each LSR establishes a forwarding path of the protection LSP according to a next hop LSR recorded in the explicit routing object, and eventually establishes the protection LSP according to the path recorded in the explicit routing object.

Step 102: after the protection LSP is established, the sink node obtains a path of the protection LSP in an MPLS network according to the explicit routing object carried in the protection LSP establishment request.

Step 103: the sink node constructs an explicit routing object carried in a return LSP establishment request along the reverse the of the path of the protection LSP, i.e. arranging all the LSRs in the reverse direction of the sequence of all the LSRs on the protection LSP path, and successively recording them in the explicit routing object carried in the return LSP establishment request; the path recorded in the explicit routing object is a reverse path of the protection LSP.

Step 104: the sink node sends the return LSP establishment request carrying the explicit routing object constructed in Step 103 to initiate the establishment of a return LSP, each LSR on the return LSP determines a next hop LSR on the return LSP according to the explicit routing object until the source node receives the explicit routing object and eventually establishes the return LSP.

As can be seen, the return LSP, the establishment of which is initiated by the sink node using the above method, is the reverse LSP of the protection LSP.

### Embodiment 2

The method for establishing a return LSP described in accordance with the present embodiment includes the following steps.

Step 201: a source node sends a protection LSP establishment request carrying a record routing object to initiate the establishment of a protection LSP on which each LSR establishes the protection LSP according to a routing algorithm and records a path of the protection LSP in a record routing object.

A source node in an MPLS network is able to establish an LSP in a hop-by-hop mode. In this mode, each LSR in the procedure of establishing the LSP determines a next hop LSR according to a certain routing algorithm. If a record routing object is carried in the protection LSP establishment request, each LSR in the procedure of establishing the LSP will record its next hop LSR, i.e. recording in the record routing object a forwarding path of the protection LSP. As a result, when the establishment of the protection LSP is finished, i.e. when the protection LSP establishment request arrives at the sink node, the record routing object of the protection LSP establishment request will record the whole path of the protection LSP.

Step 202: after the establishment of the protection LSP is finished, the sink node obtains the protection LSP in an MPLS network according to the record routing object recorded in the protection LSP establishment request.

Step 203: the sink node constructs an explicit routing object in a return LSP establishment request along the reverse of the path of the protection LSP, i.e. arranging all the LSRs in the reverse direction of the sequence of all the LSRs on the protection LSP path, and successively recording them in the explicit routing object; the path recorded in the explicit routing object is the reverse path of the protection LSP.

Step 204: the sink node sends the return LSP establishment request carrying the explicit routing object constructed in Step 203 to initiate the establishment of a return LSP, each LSR on the return LSP determines a next hop LSR on the return LSP according to the explicit routing object until the source node receives the explicit routing object and eventually establishes the return LSP.

As can be seen, the return LSP, the establishment of which is initiated by the sink node using the above method, is also a reverse LSP of the protection LSP.

The case that a sink node initiates the establishment of a protection LSP will be hereinafter described in detail. A source node is the last node in the procedure of establishing the protection LSP; therefore, the establishment of the return LSP is initiated by the source node.

### Embodiment 3

Step 301: a sink node sends a protection LSP establishment request carrying an explicit routing object to initiate the establishment of a protection LSP; each LSR on the protection LSP establishes the protection LSP according to the explicit routing object.

Step 302: after the establishment of the protection LSP is finished, a source node obtains a path of the protection LSP in an MPLS network according to the explicit routing object carried in the protection LSP establishment request.

Step 303: the source node constructs an explicit routing object in the return LSP establishment request along the reverse of the path of the protection LSP, i.e. arranging all the LSRs in the reverse direction of the sequence of all the LSRs on the protection LSP path, and successively recording them in the explicit routing object; the path recorded in the explicit routing object is the reverse path of the protection LSP.

Step 304: the source node sends a return LSP establishment request carrying the explicit routing object constructed in Step 303 to initiate the establishment of a return LSP, each LSR on the return LSP determines a next hop LSR on the LSP according to the explicit routing object until the sink node receives the explicit routing object carried in the return LSP establishment request and eventually establishes the return LSP.

As can be seen, the return LSP, the establishment of which is initiated by the source node using the above method, is the reverse LSP of the protection LSP.

### Embodiment 4

Step 401: a sink node sends a protection LSP establishment request carrying a record routing object to initiate the establishment of a protection LSP on which each LSR establishes the protection LSP according to a routing algorithm and records a path of the protection LSP in the record routing object.

Step 402: after the establishment of the protection LSP is finished, a source node acquires the protection LSP in an MPLS network according to the record routing object carried in the protection LSP establishment request.

Step 403: the source node constructs an explicit routing object in a return LSP establishment request along the reverse of the path of the protection LSP, i.e. arranging all the LSRs in the reverse direction of the sequence of all the LSRs on the protection LSP path, and successively recording them in the explicit routing object carried in the return LSP establishment request; the path recorded in the explicit routing object carried in the return LSP establishment request is the reverse path of the protection LSP.

Step 404: the source node sends the return LSP establishment request carrying the explicit routing object constructed in Step 403 to initiate the establishment of a return LSP, each LSR on the return LSP determines a next hop LSR of the return LSP according to the explicit routing object until the sink node receives the explicit routing object carried in the return LSP establishment request and eventually establishes the return LSP.

As can be seen, the return LSP, the establishment of which is initiated by the source node using the above method, is also the reverse LSP of the protection LSP.

The above Embodiments 1-4 provide methods for establishing a return LSP according to a path of a protection LSP recorded in a record routing object or an explicit routing object carried in a protection LSP establishment request to enable the established return LSP to overlap with the protection LSP, which makes it possible to guarantee the transmission of the LSP failure information via the return LSP in the case that a working LSP fails or transmission quality is impaired, thereby ensuring the normal operation of protection switching.

It should be noted that, to avoid that the protection switching is impossible to be normally performed if the return LSP fails, a protection LSP may be further established for the return LSP in accordance with an embodiment of the present invention. The established protection LSP of the return LSP may be a reverse path of the working LSP, an establishing method thereof is similar to the above method, i.e. carrying an explicit routing object or a record routing object in a working LSP establishment request to record a path of the working LSP, and establishing the protection LSP of the return LSP along the reverse path of the working LSP. In this way, it is possible to guarantee that the sink node is able to select a return LSP from the two return LSPs between the source node and the sink node. The reverse LSP of the working LSP may be used for transmitting LSP failure information in the case that the protection LSP fails, which greatly guarantees the reliability of the transmission of the LSP failure information.

The purpose, technical solution and merits of the present invention have been described in detail by the above preferred embodiments. It should be appreciated that the foregoing is only preferred embodiments of the present invention and is not for use in limiting the invention. Any modification, equivalent substitution, improvement within the spirit and principle of the present invention should be covered in the protection scope of the present invention.

What is claimed is:

1. A method for establishing a return Label Switch Path (LSP) in a Multi-Protocol Label Switching (MPLS) system, comprising:
recording, by a last node in a procedure of establishing a protection LSP, a path of the protection LSP upon establishing the protection LSP;
constructing, by the last node, a first explicit routing object along the reverse of the path of the protection LSP;
establishing, by each node on the protection LSP, a return LSP according to the first explicit routing object.

2. The method of claim 1, wherein the recording the path of the protection LSP path comprises:
obtaining the path of the protection LSP recorded in an explicit routing object or a record routing object carried in a protection LSP establishment request, and storing the path of the protection LSP.

3. The method of claim 1, wherein a node initiating to establish the protection LSP is a source node of traffic;
the last node is a sink node of the traffic.

4. The method of claim 2, wherein a node initiating to establish the protection LSP is a source node of traffic;
the last node is a sink node of the traffic.

5. The method of claim 1, wherein a node initiating to establish the protection LSP is a sink node of traffic;
the last node is a source node the traffic.

6. The method of claim 2, wherein a node initiating to establish the protection LSP is a sink node of traffic;
the last node is a source node the traffic.

7. The method of claim 1, wherein the constructing the first explicit routing object along the reverse of the path of the protection LSP comprises:
recording, according to the reverse of a sequence of all the nodes on the protection LSP, all the nodes on the protection LSP in the first explicit routing object successively.

8. The method of claim 1, further comprising:
establishing a protection LSP of the return LSP.

9. The method of claim 8, wherein the establishing the protection LSP of the return LSP comprises:
recording, by a last node in the procedure of establishing a working LSP, a path of the working LSP upon establishing the working LSP;
constructing, by the last node in the procedure of establishing a working LSP, a second explicit routing object along the reverse of the path of the working LSP;
establishing the protection LSP of the return LSP according to the second explicit routing object.

10. The method of claim 9, wherein the recording the path of the working LSP comprises:
obtaining the path of the working LSP recorded by an explicit routing object or a record routing object carried in a working LSP establishment request, and storing the path of the working LSP.

11. The method of claim 9, wherein the constructing the second explicit routing object along the reverse of the path of the working LSP comprises:
recording, according to the reverse of a sequence of all the nodes on the working LSP, all the nodes on the working LSP in the second explicit routing object successively.

12. A system for establishing a return Label Switch Path (LSP) in a Multi-Protocol Label Switching (MPLS) system, comprising:
a first node, for recording a path of a protection LSP upon establishing the protection LSP, and constructing a first explicit routing object along the reverse of the path of the protection LSP; and
at least one second node, for establishing a return LSP according to the first explicit routing object.

13. The system of claim 12, wherein the first node is further used for recording a path of a working LSP upon establishing the working LSP, and constructing a second explicit routing object along the reverse of the path of the working LSP;
the at least one second node is further used for establishing the protection LSP of the return LSP according to the second explicit routing object.

14. An apparatus for establishing a return Label Switch Path (LSP) in a Multi-Protocol Label Switching (MPLS) system, comprising:
a first unit, for recording a path of a protection LSP upon establishing the protection LSP;
a second unit, for constructing a first explicit routing object along the reverse of the path of the protection LSP;
a third unit, for establishing the return LSP according to the first explicit routing object.

15. The apparatus of claim 14, wherein the first unit is further used for recording a path of a working LSP upon establishing the working LSP;
the second unit is further used for constructing a second explicit routing object along the reverse of the path of the working LSP;
the third unit is further used for establishing the protection LSP of the return LSP according to the second explicit routing object.
